(19) United States
(12) Patent Application Publication
(10) Pub. No.: US 2018/0286697 A1
(43) Pub. Date: Oct. 4, 2018

(54) METHOD FOR SELECTIVE ETCHING OF A BLOCK COPOLYMER

(71) Applicant: COMMISSARIAT A L'ENERGIE ATOMIQUE ET AUX ENERGIES ALTERNATIVES, PARIS (FR)

(72) Inventors: Nicolas POSSEME, SASSENAGE (FR); Aurélien SARRAZIN, GRENOBLE (FR)

(21) Appl. No.: 15/759,123

(22) PCT Filed: Sep. 9, 2016
(86) PCT No.: PCT/EP2016/071268

§ 371 Date: Mar. 9, 2018

(30) Foreign Application Priority Data
Sep. 11, 2015 (FR) 1558483

(51) Int. Cl. H01L 21/311; H01L 21/02; G03F 7/00

(52) U.S. Cl. CPC H01L 21/31138; G03F 7/0002; H01L 21/02115

(57) ABSTRACT

A method for etching an assembled block copolymer layer including first and second polymer phases, in which the etching method includes exposing the assembled block copolymer layer to a plasma so as to etch the first polymer phase and simultaneously to deposit a carbon layer on the second polymer phase, wherein the plasma is formed from a gas mixture including a depolymerising gas and an etching gas selected among the hydrocarbons.

### TECHNICAL FIELD

The present invention relates to techniques of block copolymers directed self-assembly (DSA) allowing patterns of very high resolution and density to be generated. More specifically, the invention relates to an etching method making it possible to remove a first phase of a block copolymer selectively with respect to a second phase of the block copolymer.

### PRIOR ART

The resolution limit of optical lithography leads to novel techniques being explored to produce patterns of which the critical dimension (CD) is less than 22 nm. Directed self-assembly of block copolymers is considered as one of the most promising emerging lithography techniques, due to its simplicity and the low cost of its implementation.

Block copolymers are polymers in which two repeating units, a monomer A and a monomer B, form chains bound together by a covalent bond. When sufficient mobility is given to the chains, for example by heating these block copolymers, the chains of monomer A and the chains of monomer B have a tendency to separate into phases or blocks of polymer and to reorganise into specific conformations, which notably depend on the ratio between the monomer A and the monomer B. Depending on this ratio, it is possible to have spheres of A in a matrix of B, or instead cylinders of A in a matrix of B, or instead intercalated lamellas of A and lamellas of B. The size of the domains of block A (respectively block B) is directly proportional to the length of the chains of monomer A (respectively monomer B). Block copolymers thus have the property of forming polymer patterns which may be controlled thanks to the ratio of the monomers A and B.

Known block copolymer directed self-assembly (DSA) techniques may be grouped together into two categories, grapho-epitaxy and chemo-epitaxy.

Grapho-epitaxy consists in forming primary patterns called guides on the surface of a substrate, these patterns delimiting areas inside which a block copolymer layer is deposited. The guiding patterns make it possible to control the organisation of the blocks of copolymer to form secondary patterns of greater resolution inside these areas. The guiding patterns are conventionally formed by photolithography in a resin layer.

In DSA techniques using chemo-epitaxy, the substrate undergoes a chemical modification of its surface in such a way as to create zones preferentially attracting a single block of the copolymer, or neutral zones not attracting either of the two blocks of the copolymer. Thus, the block copolymer is not organised in a random manner, but according to the chemical contrast of the substrate. The chemical modification of the substrate may notably be obtained by grafting of a neutralisation layer called “brush layer”, for example formed of a random copolymer.

DSA techniques make it possible to produce different types of patterns in an integrated circuit substrate. After deposition and assembly of the block copolymer on the substrate, secondary patterns are developed by removing one of the two blocks of the copolymer, for example block A, selectively with respect to the other, thereby forming patterns in the remaining copolymer layer (block B). If the domains of block A are cylinders, the patterns obtained after removal are cylindrical holes. On the other hand, if the domains of block A are lamellas, rectilinear trench-shaped patterns are obtained. Then, these patterns are transferred by etching on the surface of the substrate, either directly in a dielectric layer, or beforehand in a hard mask covering the dielectric layer.

The block copolymer PMMA-b-PS, constituted of polymethylmethacrylate (PMMA) and polystyrene (PS), is the most studied in the literature. Indeed, the syntheses of this block copolymer and the corresponding random copolymer (PMMA-r-PS) are easy to carry out and perfectly mastered. The removal of the PMMA phase may be carried out by wet etching, optionally coupled with exposure to ultraviolet rays, or by dry etching using a plasma.

Wet etching of PMMA, for example in an acetic acid bath, is a highly selective removal technique with respect to polystyrene. The selectivity, that is to say the ratio of the etching rate of PMMA over the etching rate of polystyrene, is high (greater than 20:1). However, with this technique, etching residues are to redeposited on the etched copolymer layer, blocking part of the patterns obtained in the polystyrene layer which prevents their transfer. Moreover, in the case of lamella-shaped domains, wet etching may cause a collapse of the polystyrene structures due to considerable capillarity forces.

Dry plasma etching does not suffer from these drawbacks and has considerable economic interest, because the step of transferring the patterns that follows the step of removing the PMMA is also a plasma etching. Consequently, the same equipment may be used successively for these two steps. The plasmas normally used to etch the PMMA phase are generated from a mixture of argon and oxygen (Ar/O₂) or a mixture of oxygen and fluorocarbon gas (e.g. O₂/CHF₃). The etching of PMMA using these plasmas is however carried out with a selectivity with respect to polystyrene much lower than that of wet etching (respectively 4.2 and 3.5).

Thus, other plasmas have been developed in order to increase the selectivity of the (dry) etching of PMMA. For example, in the article [“Highly selective etch gas chemistry design for precise DSAL dry development process”, M. Omura et al., Advanced Etch Technology for Nanopatterning III, Proc. SPIE Vol. 9054, 905409, 2014], the authors show that a plasma of carbon monoxide (CO) makes it possible to etch PMMA with practically infinite selectivity. Indeed, the PMMA is etched by the CO plasma without the polystyrene being impacted, because a carbon deposit simultaneously forms on the polystyrene.

FIG. 1 is a graph that represents the etching depth in a PMMA layer and in a polystyrene (PS) layer during etching by CO plasma. It illustrates the difference in regimes between the two layers: etching regime in the case of the PMMA layer (positive etching depth) and deposition regime in the case of the PS layer (negative etching depth).

When this gas is used alone, a phenomenon of saturation takes place at around 30 s of etching, leading to stoppage of the PMMA etching. Indeed, the deposition regime progressively takes dominance over the etching regime and the PMMA etching is stopped at an etching depth of around 15 nm by the formation of a carbon layer on the partially etched layer of PMMA. It is thus not possible to etch more than 15 nm thickness of PMMA with this single gas.

To overcome this problem of saturation, carbon monoxide is mixed with hydrogen (H₂) at a concentration less than or equal to 7% and the plasma is generated at a polarisation power of around 80 W. In practice, it is observed that this gas mixture has an etching selectivity much lower than that of carbon monoxide alone, because the addition of hydrogen inhibits the deposition of the carbon layer on the polystyrene. The polystyrene is then etched at the same time as the PMMA. The result is a widening of the patterns formed in the polystyrene layer (compared to the initial dimensions of the domains of PMMA) and difficulties in transferring these patterns into the substrate. Indeed, the polystyrene layer used as mask during this transfer risks not being sufficiently thick.

### SUMMARY OF THE INVENTION

The aim of the present invention is to provide a method for dry etching a block copolymer which has high etching selectivity between the phases or blocks of the copolymer and which does not experience any limit in terms of etching depth.

According to the invention, this objective tends to be achieved by providing a method for etching an assembled block copolymer layer comprising first and second polymer phases, the etching method comprising exposing the assembled block copolymer layer to a plasma so as to etch the first polymer phase and simultaneously to deposit a carbon layer on the second polymer phase, the plasma being formed from a gas mixture comprising a depolymerising gas and an etching gas selected among the hydrocarbons.

Hydrocarbons are organic compounds constituted exclusively of carbon (C) and hydrogen (H) atoms. Their empirical formula is CₓH_{y}, where x and y are non-zero natural integers.

Like carbon monoxide (CO), a gaseous hydrocarbon may, when it is mixed with a depolymerising gas, give rise to a plasma making it possible both to etch the first phase of a block copolymer and to cover with a carbon deposit (rather than etch) the second phase of the copolymer. Thus, the etching method according to the invention is as selective as the method of the prior art, wherein the plasma is formed using carbon monoxide only. However, unlike etching by CO plasma, etching by a hydrocarbon does not result in any phenomenon of saturation. The etching of the first phase of the block copolymer continues as long as the copolymer layer is exposed to the plasma. In other words, the etching method according to the invention is not limited in terms of thickness of the block copolymer layer.

Preferably, the etching method has a ratio of the flow rate of etching gas over the flow rate of depolymerising gas comprised between 0.9 and 1.4.

The method according to the invention may also have one or more of the characteristics below, considered individually or according to all technically possible combinations thereof:

the etching gas is methane;

the etching gas is ethane;

the assembled block copolymer layer is exposed to the plasma until the first polymer phase is entirely etched;

the first polymer phase is organic and has a concentration of oxygen atoms greater than 20%;

the second polymer phase has a concentration of oxygen atoms less than 10%, and

the depolymerising gas is selected among H₂, N₂, O₂, Xe, Ar and He.

### BRIEF DESCRIPTION OF THE FIGURES

Other characteristics and advantages of the invention will become clear from the description that is given thereof below, for indicative purposes and in no way limiting, with reference to the appended figures, among which:

FIG. 1, described previously, represents the etching depth in a PMMA layer and in a polystyrene (PS) layer during etching by a carbon monoxide plasma;

FIG. 2 represents an example of an assembled block copolymer layer before the execution of the etching method according to the invention;

FIG. 3 represents the etching depth in a PMMA layer and in a polystyrene (PS) layer as a function of the time of exposure to a hydrocarbon/depolymerising gas plasma; and

FIGS. 4A and 4B represent the evolution of the copolymer layer of FIG. 2 during the etching method according to the invention.

For greater clarity, identical or similar elements are marked by identical reference signs in all of the figures.

### DETAILED DESCRIPTION OF AT LEAST ONE EMBODIMENT

FIG. 2 shows a layer 20 of assembled block copolymer before it is etched thanks to the etching method according to the invention. The copolymer layer 20 comprises first and second polymer phases, noted respectively 20A and 20B, which are organised into domains. The copolymer of the layer 20 is for example the di-block copolymer PS-b-PMMA, that is to say a copolymer constituted of polymethylmethacrylate (PMMA) and polystyrene (PS). The polymer phase 20A here corresponds to PMMA and the polymer phase 20B to polystyrene.

One way to obtain this block copolymer layer 20 consists in depositing the block copolymer PS-b-PMMA on a substrate 21 covered with a neutralisation layer 22. The neutralisation layer 22 enables the separation of the phases 20A-20B during the step of assembly of the block copolymer, in other words the organisation of the domains of the copolymer. It is for example formed of a layer of random copolymer PS-r-PMMA. Preferably, the domains of PMMA (phase 20A) are oriented perpendicularly to the substrate 21 and extend over the whole thickness of the copolymer layer 20. Depending on the ratio between PMMA and polystyrene in the copolymer PS-b-PMMA, the domains of PMMA may be cylinder-shaped (then referred to as cylindrical block copolymer) or lamella-shaped (lamellar block copolymer).

The plasma etching method described hereafter aims to etch the copolymer phase containing the most oxygen atoms (the PMMA phase 20A in the above example) selectively with respect to the other phase (the polystyrene phase 20B), and whatever the thickness of the copolymer layer 20. To this end, the copolymer layer 20 is exposed to a plasma generated from a mixture comprising at least one gaseous hydrocarbon CₓH_{y} and a depolymerising gas designated hereafter “Z”.

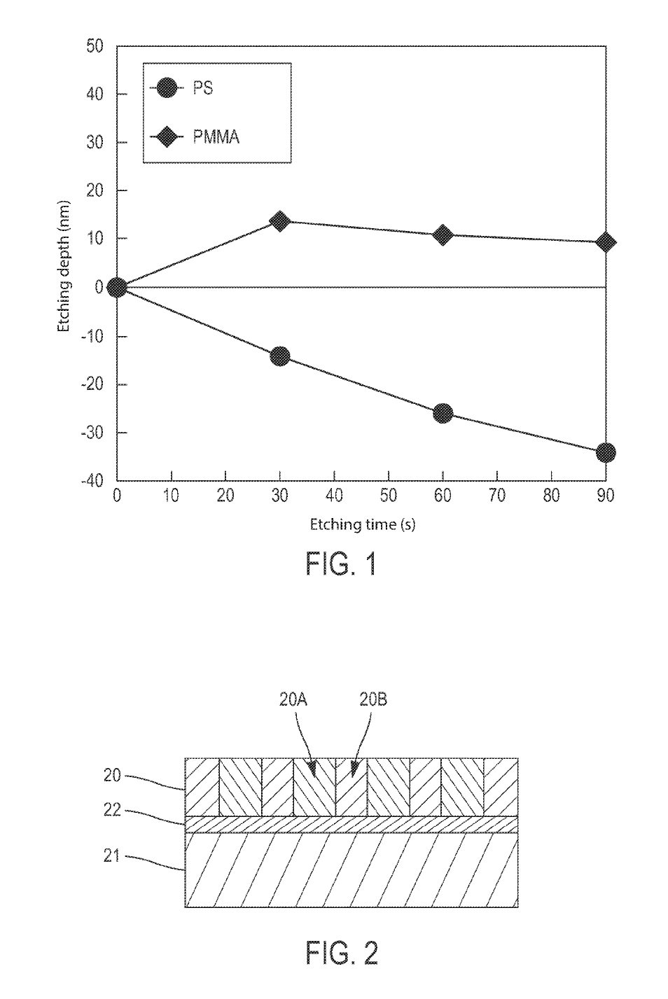

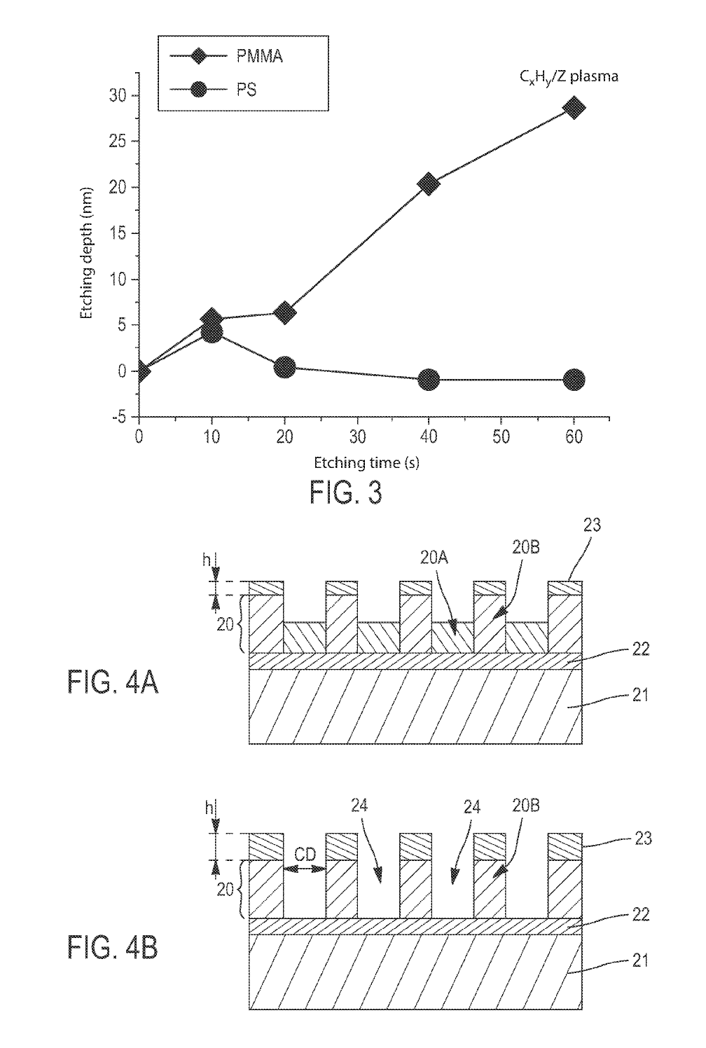

In an analogous manner to FIG. 1, FIG. 3 represents, as a function of etching time, the etching depths reached in a PMMA layer and in a polystyrene (PS) layer thanks to this type of plasma. Like the CO plasma (FIG. 1), the CₓH_{y}/Z plasma has a different behaviour according to the material of the layer. The CₓH_{y}/Z plasma acts in etching regime on the PMMA layer (represented by a positive etching depth) and in deposition regime regarding the PS layer (represented by a negative etching depth). The CₓH_{y}/Z plasma makes it possible to attain high selectivity between the PMMA and the polystyrene in so far as the polystyrene is not etched unlike the PMMA. It may further be noted in FIG. 3 that the etching depth of the CₓH_{y}/Z plasma in the PMMA layer does not reach saturation. On the contrary, it does not cease to increase as the etching progresses. This signifies that etching by CₓH_{y}/Z plasma is not limited in terms of thickness of the PMMA layer, unlike CO plasma.

FIGS. 4A and 4B represent the evolution of the copolymer layer 20 when it is exposed to the CₓH_{y}/Z plasma, in accordance with the etching method according to the invention. The PMMA phase 20A of the copolymer layer 20 is progressively etched, whereas a carbon layer 23 forms above the polystyrene phase 20B (FIG. 4A). Since the CₓH_{y}/Z plasma is not subjected to any phenomenon of saturation, the PMMA phase 20A may be etched entirely whatever its thickness, by continuing to apply the plasma on the copolymer layer 20 (FIG. 4B). For a copolymer layer 20 of thickness comprised between 20 nm and 50 nm, the time required to entirely etch the PMMA phase 20A varies between 20 s and 60 s. The thickness h of the carbon layer 23 increases during etching of the PMMA, in accordance with the teaching of FIG. 3. At the end of etching, the thickness h may be comprised between 1 nm and 3 nm.

The total removal of the PMMA phase, represented in FIG. 4B, forms patterns 24 in a layer 20 henceforth composed uniquely of the polystyrene phase 20B. These patterns 24, cylindrical hole-shaped or rectilinear trench-shaped, comes out on the neutralisation layer 22 covering the substrate 21.

The method for etching the copolymer layer 20 is advantageously carried out in a single step in a plasma reactor, either a CCP (Capacitively Coupled Plasma) or an ICP (Inductively Coupled Plasma) reactor.

The hydrocarbon in gaseous form is preferably an alkane, such as methane (CH₄) or ethane (C₂H₆), that is to say a saturated hydrocarbon. The ions of this hydrocarbon destroy the chains of the PMMA polymer by consuming the oxygen that they contain. They are also behind the formation of the carbon layer 23 on the polystyrene, the latter being insensitive to the etching because it does not contain oxygen. The ions of the depolymerising gas prevent chemical modification on the surface of the PMMA by limiting the level of polymerisation of the hydrocarbon with this material. In other words, they prevent the formation of a polymer on the surface of the PMMA. Thus, the carbon layer 23 does not cover the PMMA phase 20A. The depolymerising gas is for example selected among H₂, N₂, O₂, Xe, Ar and He.

The hydrocarbon gas CₓH_{y} and the depolymerising gas Z have input flow rates into the plasma reactor in a CₓH_{y}/Z ratio preferably comprised between 0.9 and 1.4. This ratio of flow rates is all the higher the greater the number (x) of carbon atoms in the hydrocarbon (CₓH_{y}). It is for example comprised between 0.9 and 1.2 in the case of methane (CH₄). The flow rate of hydrocarbon and the flow rate of depolymerising gas entering into the chamber of the reactor are preferably comprised between 10 sccm and 500 sccm (abbreviation for “Standard Cubic Centimetre per Minute”, i.e. the number of cm³ of gas flowing per minute in standard conditions of pressure and temperature, i.e. at a temperature of 0° C. and a pressure of 1013.25 hPa).

The other parameters of the etching plasma CₓH_{y}/Z are advantageously the following:

a power (RF) emitted by the source of the reactor comprised between 50 W and 500 W;

a polarisation power (DC or RF) of the substrate comprised between 50 W and 500 W;

a pressure in the chamber of the reactor comprised between 2.67 Pa (20 mTorr) and 16.00 Pa (120 mTorr).

As an example, the plasma is generated in a CCP reactor by mixing methane (CH₄) and nitrogen (N₂), with flow rates of 25 sccm and 25 sccm respectively, and by applying a source power of 300 W and a polarisation power of 60 W under a pressure of 4.00 Pa (30 mTorr). This plasma makes it possible to remove in 40 seconds a thickness of PMMA of around 30 nm and to deposit during the same time lapse a carbon layer of 3 nm thickness on the polystyrene.

The selectivity of etching PMMA by means of the CₓH_{y}/Z plasma, with respect to polystyrene, is particularly high given that the polystyrene phase 20B is covered with the carbon layer 23, instead of being etched. Various tests have been carried out and show that the PMMA phase of a layer of copolymer PS-b-PMMA of 50 nm thickness may be entirely etched while not consuming polystyrene. The PMMA/PS selectivity of the etching method is greater than or equal to 50. Consequently, it is possible to keep constant the critical dimension CD of the patterns 24 during the removal of the PMMA (FIG. 4B). Critical dimension is taken to mean the smallest dimension of the patterns 24 obtained by the development of the block copolymer.

Despite the differences in the plasma conditions between FIGS. 1 and 3, the two chemistries for removing PMMA selectively with respect to PS may be compared. In FIG. 3, no phenomenon of saturation is detected for the chemistry based on CₓH_{y}/Z after 30 s unlike the CO chemistry represented in FIG. 1. This non-saturation of the PMMA etching is accompanied by a slight carbon deposit on the polystyrene. This deposit considerably facilitates the step of transferring the patterns 24 into the substrate 21, which follows the step of removing the PMMA phase 20A (after opening the neutralisation layer 22). Indeed, the polystyrene phase 20B which serves as etching mask during this transfer is reinforced by the presence of the carbon layer 23. The etching mask being thicker, the constraints that bear on the choice of the plasma to carry out the transfer of the patterns 24 may be relaxed.

Although it has been described taking the copolymer PS-b-PMMA as example, the etching method according to the invention is applicable to all block copolymers comprising a first organic polymer phase (20A) rich in oxygen, that is to say having a concentration of oxygen atoms greater than 20%, and a second polymer phase (organic or inorganic) poor in oxygen, i.e. having a concentration of oxygen atoms less than 10%. This is the case notably of the di-block copolymers PS-b-PLA, PDMS-b-PMMA, PDMS-b-PLA, PDMSB-b-PLA, etc. The block copolymer may be either of cylindrical type, or of lamellar type.

Finally, the organised block copolymer layer may obviously be obtained in a different manner to that described above in relation with FIG. 2, notably by grapho-epitaxy, by chemo-epitaxy using a neutralisation layer other than a random copolymer (for example a self-assembled monolayer, SAM), or by a hybrid technique combining grapho-epitaxy and chemo-epitaxy.

1. A method for etching an assembled block copolymer layer comprising first and second polymer phases, the etching method comprising exposing the assembled block copolymer layer to a plasma so as to etch the first polymer phase and simultaneously to deposit a carbon layer on the second polymer phase, wherein the plasma is formed from a gas mixture comprising a depolymerising gas and an etching gas selected among hydrocarbons.

2. The method according to claim 1, having a ratio of the flow rate of etching gas over the flow rate of depolymerising gas comprised between 0.9 and 1.4.

3. The method according to claim 1, wherein the etching gas is methane.

4. The method according to claim 1, wherein the etching gas is ethane.

5. The method according to claim 1, wherein the assembled block copolymer layer is exposed to the plasma until the first polymer phase is entirely etched.

6. The method according to claim 1, wherein the first polymer phase is organic and has a concentration of oxygen atoms greater than 20%, and wherein the second polymer phase has a concentration of oxygen atoms less than 10%.

7. The method according to claim 1, wherein the depolymerising gas is selected among H₂, N₂, O₂, Xe, Ar and He.
